(19) United States
(12) Patent Application Publication
(10) Pub. No.: US 2026/0153557 A1
(43) Pub. Date: Jun. 4, 2026

(54) In-Situ Electrical Connectivity Detection

(71) Applicants: Advanced Micro Devices, Inc., Santa Clara, CA (US); ATI Technologies ULC, Markham (CA); Xilinx, Inc., San Jose, CA (US)

(72) Inventors: Hing Yan To, Cupertino, CA (US); Shiv Natarajan, Austin, TX (US); Anwar Parvez Kashem, Sudbury, MA (US); Alana Alexander Rutledge, Austin, TX (US); Tsun-Ho Liu, Austin, TX (US); Murali T, Austin, TX (US)

(73) Assignees: Advanced Micro Devices, Inc., Santa Clara, CA (US); ATI Technologies ULC, Markham (CA); Xilinx, Inc., San Jose, CA (US)

(21) Appl. No.: 19/406,653

(22) Filed: Dec. 2, 2025

Related U.S. Application Data
(60) Provisional application No. 63/727,602, filed on Dec. 3, 2024.

(51) Int. Cl. G01R 31/28

(52) U.S. Cl. CPC G01R 31/2837; G01R 31/2843; G01R 31/2844; G01R 31/2853; G01R 31/2856

(57) ABSTRACT

In-system electrical connectivity detection. In one or more implementations, a computing device includes a transmitter and a receiver in a package, the transmitter to transmit a signal to a separate device, the receiver to receive and measure a reflection of the transmitted signal, and the measured reflection for characterizing (e.g., testing or detecting) an electrical connection between the computing and separate devices. The computing device may characterize (e.g., detect a discontinuity in) the electrical connection by comparing a magnitude of the transmitted signal with a magnitude of the measured reflection. The computing device may be coupled with the separate device by multiple electrical connections, and the multiple electrical connections may be tested by corresponding transmitters and receivers.

### RELATED APPLICATIONS

This application claims priority to U.S. Application No. 63/727,602, titled “In-Situ LPCAMM2 Electrical Connectivity Detection,” filed Dec. 3, 2024, which is hereby incorporated by reference in its entirety.

### BACKGROUND

As computing systems grow increasingly complex, many such systems include an increasing number of components. Computing devices often include multiple semiconductor dies in a single package. Further, multiple packages and/or other devices can be assembled together on a system motherboard. To ensure system functionality, individual components, e.g., semiconductor dies, are often tested before being assembled together with other components.

### BRIEF DESCRIPTION OF THE DRAWINGS

FIG. 1 is a block diagram of a processing system configured to execute one or more applications, in accordance with one or more implementations.

FIG. 2A depicts an example of a transmitter and receiver in the processing system.

FIG. 2B depicts examples of transmission lines forming an electrical connection between a computing device and a separate device in the processing system.

FIG. 3A depicts the processing system, including the computing device and a separate device, on (and coupled through) a printed circuit board.

FIG. 3B depicts examples of processing systems having multiple electrical connections coupling a computing device and a separate device.

FIG. 4A depicts an example of automated testing the computing device in a package not coupled with a separate device.

FIG. 4B depicts an example of automated testing the computing device coupled with a separate device.

FIG. 5 depicts a procedure in an example implementation of characterizing an electrical connection.

### DETAILED DESCRIPTION

In some cases, computing systems are not fully functional when initially assembled, even when built with components that have been verified as functional. For example, components verified as functional can be mis-assembled into a non-functioning system, e.g., with connectivity faults between components. Furthermore, even if a system is determined to be completely or partially non-functional (e.g., with an open or intermittent connection between components), the exact nature and location of a defect or fault is not always known or easily detectable, which hinders troubleshooting and re-work efforts, as well as any potential design improvements. Additionally, systems that are initially assembled and connected properly can lose connectivity, e.g., when operating at increased temperature or under other typical stresses.

Techniques and structures for characterizing in-system electrical connections, such as detecting connection discontinuities, are described herein. To test an electrical connection between two devices (e.g., components of a processing system), a first device transmits a signal to a second device and awaits a response, like a controller device after sending a querying ping to a satellite device. The transmitted signal can be a step or pulse signal, etc., and can be analogized to a sonar ping sent to the second device. The first device (e.g., a processing or computing device) stands by after transmitting the signal or ping, prepared for the response: a reflection (or not) of the transmitted signal from a discontinuity in the electrical connection or from a termination at the second device. The first device receives and measures the reflection, which provides information to the first device about the electrical connection.

The size or magnitude of the reflection provides information about the nature of the termination or discontinuity, such as the scale of an impedance mismatch between a line impedance of the electrical connection and the termination or discontinuity. If the electrical connection does not have any connectivity faults, such as an open, and a termination impedance is perfectly matched (or substantially matched) to the line impedance, the energy of the signal will be perfectly (or substantially) transferred to and absorbed by the termination. If the energy of the signal is not perfectly transferred to the termination, unabsorbed energy will reflect back towards the termination, with larger impedance mismatches causing larger reflections. Perfectly bad impedance mismatches (e.g., perfect opens or shorts), whether at the line termination or somewhere along the electrical connection, cause the entire signal to be reflected back towards the transmitter of the signal.

As with the case of a sonar ping, a time measured between transmitting the ping signal and receiving the reflection of the signal provides information about the location of the termination or discontinuity, e.g., a distance from the signal transmitter. Since the signal ping must propagate down the electrical connection to the termination or discontinuity and the reflection must propagate back up the electrical connection, the time elapsed and measured between the transmitting and receiving informs the first device (given knowledge about the propagation speed of the signal) how far down the line of the electrical connection the termination or discontinuity is.

Using the described techniques, the electrical connectivity of a system can be confirmed (or a discontinuity detected) without disturbing the system components, e.g., without needing to disassemble the system or take X-rays of soldered joints or other interconnections. The described techniques provide the capability to detect not only whether there is or is not an electrical connection (e.g., not only perfect opens or shorts), but also intermediate connectivity issues, such as a dry solder joint or other suboptimal connection. Rather than requiring additional (e.g., test) hardware, a processing or computing system can utilize existing hardware to perform at least some of the described techniques, e.g., by configuring an input/output (I/O) device of the system to transmit an appropriate signal out an I/O line and to receive and measure a reflection of the signal.

One or more of the I/O devices of the system can be reconfigured to perform the described techniques, e.g., all of the I/Os of a processing or computing device coupled with a memory device or only a sufficiently large sample. In one example, a computing device is coupled to a memory device (e.g., a compression-attached memory module (CAMM)) by hundreds of I/O lines, but only a representative sample of the CAMM connections are tested (e.g., enough to span the footprint of the CAMM). Alternatively or additionally, some or all of the connections are tested under varying conditions and/or at different times, such as at different temperatures, during boot-up, or when there is a communication problem with the coupled device. The described techniques, which are capable of detecting discontinuities under actual operating conditions in application environments, enable increased manufacturing and assembly yields, as well as advancements in trouble shooting, failure analysis, and design.

In some aspects, the techniques described herein relate to a computing device, including a transmitter in a package, the transmitter coupled to an interface of the package and configured to transmit a signal to a separate device via the interface, and a receiver in the package, the receiver coupled to the interface and configured to receive and measure a reflection of the transmitted signal, the measured reflection used to characterize an electrical connection between the computing device and the separate device.

In some aspects, the techniques described herein relate to a computing device, wherein the computing device is configured to characterize the electrical connection based on a comparison between a first magnitude of the transmitted signal and a second magnitude of the measured reflection.

In some aspects, the techniques described herein relate to a computing device, wherein the measured reflection is used to detect a discontinuity in the electrical connection.

In some aspects, the techniques described herein relate to a computing device, wherein the computing device includes a system on a chip in the package, the system on the chip includes the transmitter and the receiver, the separate device is a memory device, the interface of the package is a first conductive pad on the package, and the interface of the package is coupled with an interface on the memory device, the interface on the memory device a second conductive pad on the memory device.

In some aspects, the techniques described herein relate to a computing device, wherein the transmitter is configured to communicate the signal to the separate device via a transmission line between the computing device and the separate device, and the receiver is configured to receive the reflection of the transmitted signal communicated via the transmission line between the computing device and the separate device.

In some aspects, the techniques described herein relate to a computing device, wherein the package is coupled with a substrate, the substrate including a first interface of the substrate coupled with the interface of the package, the separate device is coupled with the substrate, the substrate including a second interface of the substrate and an electrical trace, the electrical trace coupling the first interface of the substrate and the second interface of the substrate, the second interface of the substrate coupled with an interface of the separate device, and the electrical connection includes the electrical trace and the interface of the package, the first interface of the substrate and the second interface of the substrate, and the interface of the separate device.

In some aspects, the techniques described herein relate to a computing device, wherein the package is coupled with the substrate by a socket, the socket coupling the interface of the package and the first interface of the substrate.

In some aspects, the techniques described herein relate to a computing device, further including a plurality of transmitters, including the transmitter, a plurality of receivers, including the receiver, and a plurality of interfaces, including the interface of the package, wherein the computing device is coupled with a substrate by the plurality of interfaces and with the separate device by the substrate, a plurality of electrical connections is between the computing device and the separate device, the plurality of electrical connections including the electrical connection, and the computing device is configured to characterize the plurality of electrical connections.

In some aspects, the techniques described herein relate to a computing device, wherein the measured reflection of the transmitted signal is compared to a reference voltage, and the receiver is configured to adjust the reference voltage.

In some aspects, the techniques described herein relate to a computing device, wherein the receiver is configured to adjust a load impedance of the receiver.

In some aspects, the techniques described herein relate to a computing device, wherein the computing device is configured to measure a time between transmission of the signal and receipt of the reflection of the transmitted signal, the time used to calculate a location of a discontinuity.

In some aspects, the techniques described herein relate to a computing device, wherein the computing device is coupled with a substrate and with the separate device by the substrate, the electrical connection between the computing device and a first interface of the separate device, the computing device and the separate device are coupled through the substrate by a second interface of the separate device, and the computing device is configured to set a termination impedance of the electrical connection at the first interface of the separate device by transmitting a control signal to the separate device via the second interface of the separate device.

In some aspects, the techniques described herein relate to a computer-implemented method, including transmitting a signal out from a package interface of a computing device, receiving and measuring a reflection of the signal at the package interface, and characterizing an electrical connection to the package interface based on the measured reflection.

In some aspects, the techniques described herein relate to a computer-implemented method, wherein a separate device is coupled to the computing device at the package interface and through the electrical connection, the characterizing the electrical connection to the package interface is based on a magnitude of the measured reflection, and the characterizing the electrical connection includes testing a continuity of the electrical connection between the computing device and the separate device.

In some aspects, the techniques described herein relate to a computer-implemented method, wherein the characterizing the electrical connection to the package interface includes measuring a time between transmission of the signal and receipt of the reflection, and calculating a location of a discontinuity in the electrical connection using the time.

In some aspects, the techniques described herein relate to a computer-implemented method, further including receiving test instructions from a second device, and transmitting test results to the second device.

In some aspects, the techniques described herein relate to a computing system, including a package on a substrate, a first interconnect interface of the package coupled with a second interconnect interface of the substrate, the package configured to couple with one or more devices through the substrate, a transmitter in the package, the transmitter coupled to the first interconnect interface and configured to transmit a signal from the package to at least one device of the one or more devices via the second interconnect interface, and a receiver in the package, the receiver coupled to the first interconnect interface and configured to measure a reflection of the transmitted signal, the measured reflection used to characterize an electrical connection between the package and the at least one device.

In some aspects, the techniques described herein relate to a computing system, wherein the substrate includes an electrical trace, the electrical trace coupling the transmitter and the receiver with the at least one device, the electrical connection including the electrical trace and the first interconnect interface and the second interconnect interface, and a system on a chip in the package includes the transmitter and the receiver, the system on the chip configured to test a continuity of the electrical connection using the measured reflection.

In some aspects, the techniques described herein relate to a computing system, wherein the computing system is configured to measure a time between transmission of the signal and receipt of the reflection of the transmitted signal, characterize the electrical connection based on a magnitude of the measured reflection, and calculate a location of a discontinuity of the electrical connection using the time.

In some aspects, the techniques described herein relate to a computing system, further including the at least one device, wherein the first interconnect interface is one of a plurality of third interconnect interfaces, the package including the third interconnect interfaces coupled with a plurality of transmitters and a plurality of receivers in the package, the second interconnect interface is one of a plurality of fourth interconnect interfaces, the substrate including the fourth interconnect interfaces, the package is coupled with the substrate by the third interconnect interfaces and the fourth interconnect interfaces, the at least one device includes a plurality of fifth interconnect interfaces, the substrate includes a plurality of sixth interconnect interfaces, the at least one device is coupled with the substrate by the fifth interconnect interfaces and the sixth interconnect interfaces, and the package is coupled with the at least one device by the third interconnect interfaces, the fourth interconnect interfaces, the fifth interconnect interfaces, and the sixth interconnect interfaces.

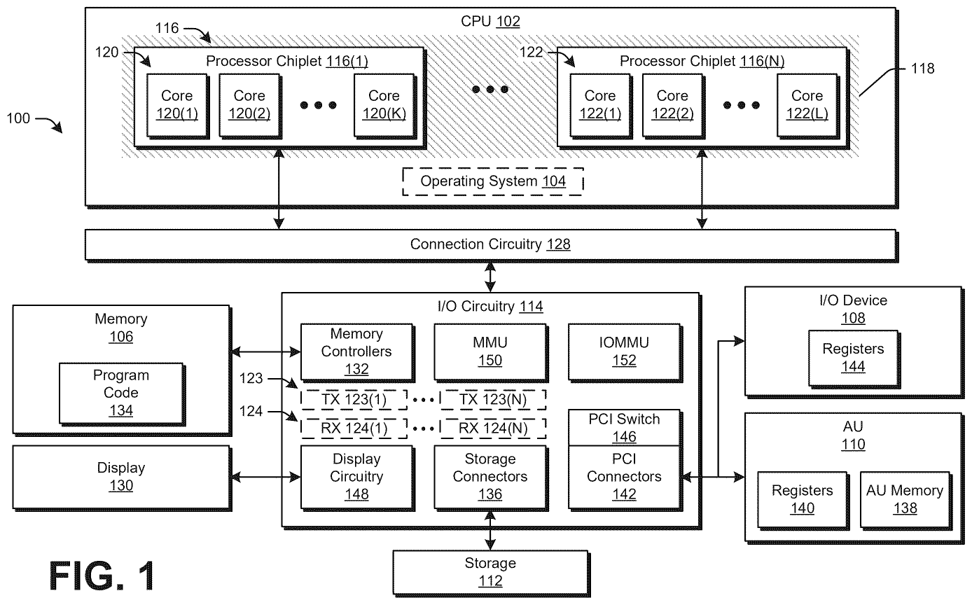

FIG. 1 is a block diagram of a processing system configured to execute one or more applications, in accordance with one or more implementations.

FIG. 1 includes a processing system 100 configured to execute one or more applications, such as compute applications (e.g., machine-learning applications, neural network applications, high-performance computing applications, databasing applications, gaming applications), graphics applications, and the like. Examples of devices in which the processing system is implemented include, but are not limited to, a server computer, a personal computer (e.g., a desktop or tower computer), a smartphone or other wireless phone, a tablet or phablet computer, a notebook computer, a laptop computer, a wearable device (e.g., a smartwatch, an augmented reality headset or device, a virtual reality headset or device), an entertainment device (e.g., a gaming console, a portable gaming device, a streaming media player, a digital video recorder, a music or other audio playback device, a television, a set-top box), an Internet of Things (IoT) device, an automotive computer or computer for another type of vehicle, a networking device, a medical device or system, and other computing devices or systems.

In the illustrated example, the processing system 100 includes a central processing unit (CPU) 102. In one or more implementations, the CPU 102 is configured to run an operating system (OS) 104 that manages the execution of applications. For example, the OS 104 is configured to schedule the execution of tasks (e.g., instructions) for applications, allocate portions of resources (e.g., system memory 106, CPU 102, input/output (I/O) device 108, accelerator unit (AU) 110, storage 112, I/O circuitry 114) for the execution of tasks for the applications, provide an interface to I/O devices (e.g., I/O device 108) for the applications, or any combination thereof.

The CPU 102 includes one or more processor chiplets 116, which are communicatively coupled together by a data fabric 118 in one or more implementations.

Each of the processor chiplets 116, for example, includes one or more processor cores 120, 122 configured to concurrently execute one or more series of instructions, also referred to herein as “threads,” for an application. Further, the data fabric 118 communicatively couples each processor chiplet 116(N) of the CPU 102 such that each processor core (e.g., processor cores 120) of a first processor chiplet (e.g., processor chiplet 116(1)) is communicatively coupled to each processor core (e.g., processor cores 122) of one or more other processor chiplets 116. Though the example presented in FIG. 1 shows a first processor chiplet (processor chiplet 116(1)) having three processor cores (120(1), 120(2), 120(K)) representing a K number of processor cores 122 and a second processor chiplet (116(N)) having three processor cores (e.g., 122(1), 122(2), 122(L)) representing an L number of processor cores 122 (L being an integer number greater than or equal to one), in other implementations, each processor chiplet 116 has any number of suitable processor cores 120, 122. For example, each processor chiplet 116 can have the same number of processor cores 120, 122 as one or more other processor chiplets 116, a different number of processor cores 120, 122 as one or more other processor chiplets 116, or both.

Examples of connections which are usable to implement data fabric include, but are not limited to, buses (e.g., a data bus, a system, an address bus), interconnects, memory channels, through-silicon vias, traces, and planes. Other example connections include optical connections, fiber optic connections, and/or connections or links based on quantum entanglement.

In this example, one or more transmitters 123 (e.g., transmitters 123(1) through 123(N)) and one or more receivers 124 (e.g., receivers 124(1) through 124(N) are depicted in the I/O circuitry 114. In variations, however, the transmitters 123 and receivers 124 are included in and/or are implemented by one or more different and/or additional components of the processing system 100, such as the CPU 102, the memory 106, the I/O device 108, the AU 110, the storage 112, and so forth. In at least one implementation, the transmitters 123 and/or receivers 124 or portions of the transmitters 123 and/or receivers 124 are included in at least two of the depicted components of the processing system 100. By way of example, the receivers 124 are included in or otherwise implemented by at least the I/O circuitry 114 and connection circuitry 128 in at least one variation.

Additionally, within the processing system 100, the CPU 102 is communicatively coupled to an I/O circuitry 114 by the connection circuitry 128. For example, each processor chiplet 116 of the CPU 102 is communicatively coupled to the I/O circuitry 114 by the connection circuitry 128. The connection circuitry 128 includes, for example, one or more data fabrics, buses, buffers, queues, and the like. The I/O circuitry 114 is configured to facilitate communications between two or more components of the processing system 100 such as between the CPU 102, system memory 106, display 130, universal serial bus (USB) devices, peripheral component interconnect (PCI) devices (e.g., I/O device 108, AU 110), storage 112, and the like.

As an example, system memory 106 includes any combination of one or more volatile memories and/or one or more non-volatile memories, examples of which include dynamic random-access memory (DRAM), static random-access memory (SRAM), non-volatile RAM, and the like. To manage access to the system memory 106 by CPU 102, the I/O device 108, the AU 110, and/or any other components, the I/O circuitry 114 includes one or more memory controllers 132. These memory controllers 132, for example, include circuitry configured to manage and fulfill memory access requests issued from the CPU 102, the I/O device 108, the AU 110, or any combination thereof. Examples of such requests include read requests, write requests, fetch requests, pre-fetch requests, or any combination thereof. That is to say, these memory controllers 132 are configured to manage access to the data stored at one or more memory addresses within the system memory 106, such as by CPU 102, the I/O device 108, and/or the AU 110.

When an application is to be executed by processing system 100, the OS 104 running on the CPU 102 is configured to load at least a portion of program code 134 (e.g., an executable file) associated with the application from, for example, a storage 112 into system memory 106. This storage 112, for example, includes a non-volatile storage such as a flash memory, solid-state memory, hard disk, optical disc, or the like configured to store program code 134 for one or more applications.

To facilitate communication between the storage 112 and other components of processing system 100, the I/O circuitry 114 includes one or more storage connectors 136 (e.g., universal serial bus (USB) connectors, serial AT attachment (SATA) connectors, PCI Express (PCIe) connectors) configured to communicatively couple storage 112 to the I/O circuitry 114 such that I/O circuitry 114 is capable of routing signals to and from the storage 112 to one or more other components of the processing system 100.

In association with executing an application, in one or more scenarios, the CPU 102 is configured to issue one or more instructions (e.g., threads) to be executed for an application to the AU 110. The AU 110 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable logic devices (FPGAs)), or any combination thereof.

In at least one example, the AU 110 includes one or more compute units that concurrently execute one or more threads of an application and store data resulting from the execution of these threads in AU memory 138. This AU memory 138, for example, includes any combination of one or more volatile memories and/or non-volatile memories, examples of which include caches, video RAM (VRAM), or the like. In one or more implementations, these compute units are also configured to execute these threads based on the data stored in one or more physical registers 140 of the AU 110.

To facilitate communication between the AU 110 and one or more other components of processing system 100, the I/O circuitry 114 includes or is otherwise connected to one or more connectors, such as PCI connectors 142 (e.g., PCIe connectors) each including circuitry configured to communicatively couple the AU 110 to the I/O circuitry such that the I/O circuitry 114 is capable of routing signals to and from the AU 110 to one or more other components of the processing system 100. Further, the PCIe connectors 142 are configured to communicatively couple the I/O device 108 to the I/O circuitry 114 such that the I/O circuitry 114 is capable of routing signals to and from the I/O device 108 to one or more other components of the processing system 100.

By way of example and not limitation, the I/O device 108 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 108 is configured to execute one or more operations, tasks, instructions, or any combination thereof based on one or more physical registers 144 of the I/O device 108. In one or more implementations, such physical registers 144 are configured to maintain data (e.g., operands, instructions, values, variables) indicating one or more operations, tasks, or instructions to be performed by the I/O device 108.

To manage communication between components of the processing system 100 (e.g., AU 110, I/O device 108) that are connected to PCI connectors 142, and one or more other components of the processing system 100, the I/O circuitry 114 includes PCI switch 146. The PCI switch 146, for example, includes circuitry configured to route packets to and from the components of the processing system 100 connected to the PCI connectors 142 as well as to the other components of the processing system 100. As an example, based on address data indicated in a packet received from a first component (e.g., CPU 102), the PCI switch 146 routes the packet to a corresponding component (e.g., AU 110) connected to the PCI connectors 142.

Based on the processing system 100 executing a graphics application, for instance, the CPU 102, the AU 110, or both are configured to execute one or more instructions (e.g., draw calls) such that a scene including one or more graphics objects is rendered. After rendering such a scene, the processing system 100 stores the scene in the storage 112, displays the scene on the display 130, or both. The display 130, for example, includes a cathode-ray tube (CRT) display, liquid crystal display (LCD), light emitting diode (LED) display, organic light emitting diode (OLED) display, or any combination thereof. To enable the processing system 100 to display a scene on the display 130, the I/O circuitry 114 includes display circuitry 148. The display circuitry 148, for example, includes high-definition multimedia interface (HDMI) connectors, DisplayPort connectors, digital visual interface (DVI) connectors, USB connectors, and the like, each including circuitry configured to communicatively couple the display 130 to the I/O circuitry 114. Additionally or alternatively, the display circuitry 148 includes circuitry configured to manage the display of one or more scenes on the display 130 such as display controllers, buffers, memory, or any combination thereof.

Further, the CPU 102, the AU 110, or both are configured to concurrently run one or more virtual machines (VMs), which are each configured to execute one or more corresponding applications. To manage communications between such VMs and the underlying resources of the processing system 100, such as any one or more components of processing system 100, including the CPU 102, the I/O device 108, the AU 110, and the system memory 106, the I/O circuitry 114 includes memory management unit (MMU) 150 and input-output memory management unit (IOMMU) 152. The MMU 150 includes, for example, circuitry configured to manage memory requests, such as from the CPU 102 to the system memory 106. For example, the MMU 150 is configured to handle memory requests issued from the CPU 102 and associated with a VM running on the CPU 102. These memory requests, for example, request access to read, write, fetch, or pre-fetch data residing at one or more virtual addresses (e.g., guest virtual addresses) each indicating one or more portions (e.g., physical memory addresses) of the system memory 106. Based on receiving a memory request from the CPU 102, the MMU 150 is configured to translate the virtual address indicated in the memory request to a physical address in the system memory 106 and to fulfill the request. The IOMMU 152 includes, for example, circuitry configured to manage memory requests (memory-mapped I/O (MMIO) requests) from the CPU 102 to the I/O device 108, the AU 110, or both, and to manage memory requests (direct memory access (DMA) requests) from the I/O device 108 or the AU 110 to the system memory 106. For example, to access the registers 144 of the I/O device 108, the registers 140 of the AU 110, and/or the AU memory 138, the CPU 102 issues one or more MMIO requests. Such MMIO requests each request access to read, write, fetch, or pre-fetch data residing at one or more virtual addresses (e.g., guest virtual addresses) which each represent at least a portion of the registers 144 of the I/O device 108, the registers 140 of the AU 110, or the AU memory 138, respectively. As another example, to access the system memory 106 without using the CPU 102, the I/O device 108, the AU 110, or both are configured to issue one or more DMA requests. Such DMA requests each request access to read, write, fetch, or pre-fetch data residing at one or more virtual addresses (e.g., device virtual addresses) which each represent at least a portion of the system memory 106. Based on receiving an MMIO request or DMA request, the IOMMU 152 is configured to translate the virtual address indicated in the MMIO or DMA request to a physical address and fulfill the request.

In variations, the processing system 100 can include any combination of the components depicted and described. For example, in at least one variation, the processing system 100 does not include one or more of the components depicted and described in relation to FIG. 1. Additionally or alternatively, in at least one variation, the processing system 100 includes additional and/or different components from those depicted. The processing system 100 is configurable in a variety of ways with different combinations of components in accordance with the described techniques.

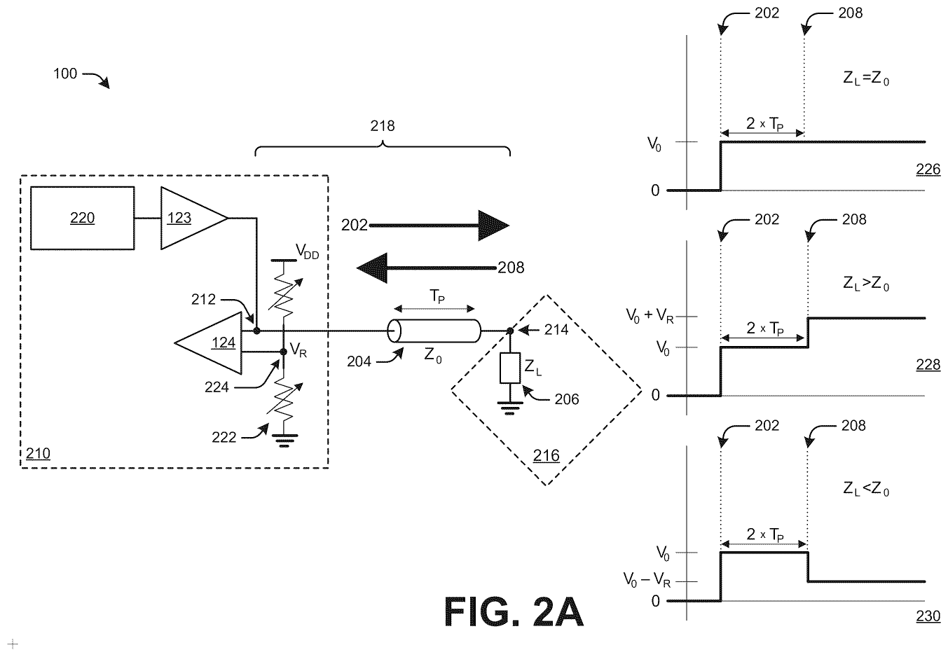

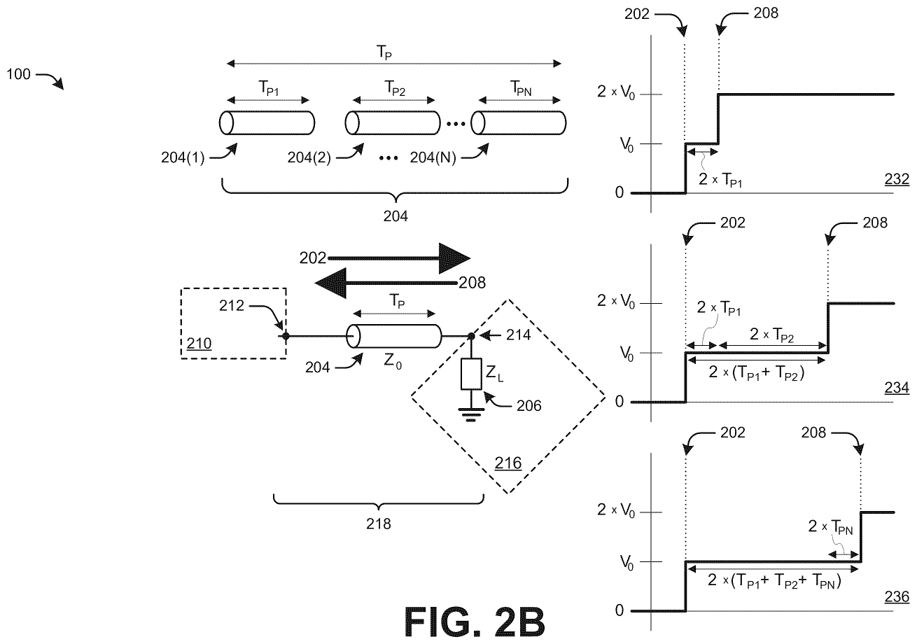

FIGS. 2A and 2B are block diagrams of a computing device with a transmitter and receiver and with an electrical connection to a separate device.

FIG. 2A depicts an example of the transmitter 123 and receiver 124 in the processing system 100. The transmitter 123 is configured to transmit a signal 202 via (e.g., through) a transmission line 204 to a termination 206, and the receiver 124 is configured to receive and measure a reflection 208 of the transmitted signal 202. In some scenarios, at least some of the signal 202 transmitted by the transmitter 123 to the termination 206 is reflected back through the transmission line 204 to the receiver 124, for example, when there is an impedance mismatch between a characteristic impedance (Z₀) of the transmission line 204 and a load impedance (Z_{L}) of the termination 206. In the cases of connectivity faults (such as opens or shorts) along the line 204 (including on either end), the transmission of the signal 202 by the transmitter 123 and the receipt and measurement of the reflection 208 by the receiver 124 enables the detection and location of the fault. In one or more implementations, the transmitter 123 and receiver 124 are included in I/O hardware of processing system 100, such as I/O circuitry 114, e.g., to transmit and receive data to and from memory 106 or one or more other components shown (or not shown) in FIG. 1.

A computing device 210 includes both the transmitter 123 and receiver 124 in an integrated circuit (IC) package, and both the transmitter 123 and receiver 124 are coupled to an interconnect interface of the device 210. In this context, the term “coupled” refers to a direct or indirect connection, such as a direct (electrical, mechanical, etc.) connection between the coupled things or an indirect connection, e.g., through one or multiple intermediate things. In FIG. 2A, a node 212 represents the interconnect interface of the package of the device 210, e.g., of the processing system 100. In one or more examples, the processing system 100 includes the computing device 210 (e.g., as a portion of the processing system 100 that includes at least the transmitter 123 and receiver 124 and the CPU 102). In one example in which the processing system 100 includes the computing device 210, the system 100 includes a second device 216, e.g., as (or part of) memory 106, I/O device 108, AU 110, display 130, etc. In another example, the computing device 210 includes the processing system 100.

In at least one implementation, the node 212 (and corresponding interconnect interface) is on an outer surface of the package of the device 210. The transmission line 204 couples the node 212 (and the transmitter 123 and receiver 124) with a node 214, which represents an interconnect interface of the second device 216. In one or more implementations, the transmission line 204 is or includes an electrical trace, e.g., in a printed circuit board (PCB) or other substrate, and the electrical trace (and, e.g., the PCB or other substrate) couples the transmitter 123 and receiver 124 with the second device 216.

The transmission line 204 is part of an electrical connection 218 between the computing device 210 and the separate device 216. The electrical connection 218 also includes the interconnect interfaces represented by nodes 212, 214. Although FIG. 2A illustrates lines coupling nodes 212, 214 with the transmission line 204, in at least some cases, the transmission line 204 can be considered to include nodes 212, 214 (e.g., portions of the devices 210, 216) and to, for example, couple the transmitter 123 and/or receiver 124 with the termination 206.

An interconnect interface is a structure on a device (e.g., a semiconductor die, an IC package, a memory device (such as a memory module), a socket or other connector (such as a peripheral connector), etc.) or substrate for coupling (e.g., interfacing) electrical interconnects. Examples of interconnect interfaces include (e.g., copper) bond pads, solder bumps or microbumps, package pins (e.g., in a pin grid array (PGA)), lands (e.g., in a land grid array (LGA)), solder balls (e.g., in a ball grid array (BGA)), socket pins, and other contacts. In one or more cases, such as direct-bonded pads on hybrid-bonded semiconductor dies, some coupled interconnect interfaces are directly connected. Notably, in at least one implementation, two coupled interconnect interfaces are indirectly coupled, for example, with both interconnect interfaces directly connected to (e.g., in contact with) the same or different intermediate interconnect interface(s). In one such example, two bond or land pads are coupled by solder or a socket between the pads.

The second device 216 includes the termination 206 and is separate from the computing device 210. In one or more implementations, the computing device 210 is in an IC package on a motherboard (or other substrate) and electrically connected to the separate device 216 on the same motherboard as (but separate from) the device 210. In at least one implementation, the separate device 216 is part of (e.g., not separate from) the processing system 100, though separate from the transmitter 123, the receiver 124, and the device 210. In one example, the computing device 210 and the separate device 216 are separate dies in the same IC package. In some implementations, the separate device 216 is a memory device 216, whether a DRAM or not, such as a high-bandwidth memory (HBM), a compression attached memory module (CAMM), CAMM2, low-power CAMM2 (LPCAMM2), etc. In other implementations, the separate device 216 is some other type of device 216, whether described at FIG. 1 (such as an I/O device 108, an AU 110, a display 130, etc.) or not.

The transmitter 123 is configured to transmit a signal (e.g., the signal 202), for example, from a package of the device 210, to the separate device 216 via a first interconnect interface (e.g., represented by the node 212) and via a second interconnect interface (e.g., represented by the node 214) of the separate device 216. The transmitter 123 is configured to communicate the signal (e.g., signal 202) to the separate device 216 via the transmission line 204 (e.g., an electrical trace) between the devices 210, 216. In variations, the signal 202 is adjustable (e.g., with different magnitude values and/or with different shapes or profiles).

The transmitter 123 transmits I/O signals 202 (e.g., data streams) from the computing device 210 to the separate device 216, in one or more scenarios (e.g., during normal operations of the devices 210, 216). In at least one implementation, the signal 202 is created by a pattern generator 220, e.g., pulsing out the signal 202. In an example, the transmitter 123 is part of an I/O device (or portion of the device 210) that creates, e.g., pulses out, the signal 202 (and, e.g., other signals) defined for, and fed to, the transmitter 123 by the pattern generator 220. In at least one example, the pattern generator 220 sends a signal (e.g., a pulse or a step signal) through the transmitter 123, and the signal 202 propagates down the transmission line 204 with a delay or propagation time (T_{P}) across the transmission line 204. In one or more variations, the transmission line 204 constitutes all (or at least the vast majority) of the electrical connection 218 between the devices 210, 216, and the propagation time T_{P} of the signal 202 across the transmission line 204 is substantially equal to a propagation time T_{P} of the signal 202 between the devices 210, 216.

In some electrical fault detection scenarios (e.g., when checking for discontinuities between the devices 210, 216), the pattern generator 220 is triggered to provide a signal 202 (e.g., a pulse or a step signal 202), and the signal 202 is output (e.g., transmitted by the transmitter 123) and then (at least some portion) is reflected back, for example, depending on the load impedance Z_{L} of the termination 206 or whether there is a discontinuity in the electrical connection 218 between the devices 210, 216. In at least one example, the reflection 208 of the transmitted signal 202 propagates back up the transmission line 204 (e.g., from the separate device 216 to the computing device 210) with the propagation time T_{P}.

The receiver 124 is configured to receive and measure the reflection 208 of the transmitted signal 202 (e.g., the transmitted signal 202 communicated via the transmission line 204 between the computing device 210 and the separate device 216). The receiving and measuring of the reflection 208 enables the checking of the connection 218, e.g., for connection faults at interfaces between the devices 210, 216 and over the line 204. In one or more implementations, the measured reflection 208 is used to detect a discontinuity in the electrical connection 218. In an example, the computing device 210 is configured to detect the discontinuity in the connection 218 based on a magnitude of the measured reflection 208. The discontinuity can be detected by an evaluation of reflection 208, e.g., relative to an expected value. For example, gross discontinuities in the electrical connection 218 (such as shorts to ground or opens) can be detected by the reception and measurement of a large reflection 208, whether of positive or negative polarity. Smaller discontinuities in the connection 218 cause smaller (positive or negative) reflections 208. In one variation, the computing device 210 evaluates the electrical connection 218 (e.g., provides a passing or failing result) based on a size of the reflection 208 (e.g., relative to certain thresholds, such as test limits bracketing an expected value).

In at least one implementation, the measured reflection 208 is used to characterize the electrical connection 218 between the devices 210, 216, e.g., between the separate device 216 and a package of the computing device 210. In an example, the computing or processing system 100 (e.g., the computing device 210 specifically) is configured to characterize the electrical connection 218 based on a magnitude of the measured reflection 208. In another example, the computing device 210 is configured to characterize the connection 218 based on the magnitudes of multiple measured reflections 208. The computing device 210 (e.g., including the receiver 124 and, for example, in coordination with the CPU 102 and/or the AU 110) is configured to characterize the electrical connection 218 based on a comparison between a magnitude of the transmitted signal 202 and a magnitude of the reflection 208 measured by the receiver 124, in at least one variation. The characterization of the connection 218 between devices 210, 216 can include the identification of multiple small discontinuities that cause multiple small reflections 208 and multiple small corresponding variances from the expected measurement, e.g., of no variance for a perfectly matched termination.

Multiple signals 202 (or, e.g., compound signals 202 with multiple steps or pulses, etc.) can be used, e.g., to more thoroughly characterize the electrical connection 218 or to verify (double-check) one or more results, such as a detection of a discontinuity in the connection 218. In one scenario, the utilization of additional or more complex signals 202 only after an initial discontinuity detection, e.g., to minimize or balance measurement or processing costs, such as of bandwidth. In one or more implementations, the receiver 124 includes (for example, beyond the, e.g., amplifier, circuitry illustrated in FIG. 2A) at least processing functionality (e.g., capable of measuring and analyzing received signals, such as the reflection 208) and an impedance network 222. In at least one implementation, the receiver 124 includes the CPU 102 and/or the AU 110 (or at least a portion of the CPU 102 or the AU 110). In another implementation, the CPU 102 and/or the AU 110 processes measurements made by the receiver 124 (such as of the reflection 208) and characterizes the electrical connection 218 based on a comparison between a magnitude of the transmitted signal 202 and a magnitude of the reflection 208.

The detecting of discontinuities in the electrical connection 218 and the characterizing the electrical connection 218 is discussed further elsewhere herein, e.g., at example plots here at FIG. 2A and at FIG. 2B.

In the example of FIG. 2A, the receiver 124 includes the impedance network 222, by which the receiver 124 is configured to adjust a load impedance of the receiver 124 and a reference voltage at a node 224 (e.g., for comparison by the receiver 124 with a voltage sensed at node 212). In one or more implementations, the measured reflection 208 of the transmitted signal 202 is compared to the reference voltage at node 224, and the receiver 124 is configured to adjust the reference voltage at node 224, e.g., based on an initial voltage V₀ of the transmitted signal 202 and/or an expected load impedance Z_{L} of the termination 206.

In the following example scenarios (e.g., examples 226, 228, 230 of FIG. 2A), a step signal 202 of voltage V₀ is transmitted by the transmitter 123 from the computing device 210, down the transmission line 204 towards the second device 216. The plots of examples 226, 228, 230 show a voltage magnitude on the vertical axis (e.g., as measured at node 212 by the receiver 124) and an elapsed time on the horizontal axis (e.g., a time 2×T_{P}, twice the propagation time T_{P}, measured between the transmission of the signal 202 and the receipt of the reflection 208 of the transmitted signal 202). The transmitted signal 202 takes the propagation time T_{P} to propagate down the transmission line 204 between devices 210, 216 (e.g., from node 212 to node 214), and the reflection 208 takes the propagation time T_{P} again to propagate back up the transmission line 204 between devices 210, 216 (e.g., from node 214 to node 212). On the example plots, the times of the transmission and receipt of the signal 202 and reflection 208 are indicated by the dotted lines.

In the example 226, the load under consideration (e.g., termination 206 with impedance Z_{L}) is matched to the impedance Z₀ of line 204 (e.g., precluding a reflection 208), and an observed equilibrium value (e.g., the combination or superposition of signal 202 and reflection 208) at the receiver 124 (e.g., at node 212) is equal to the transmitted voltage V₀ of signal 202 (e.g., with voltage V₀ distributed evenly between the transmission line 204 impedance Z₀ and the matched load termination 206 impedance Z_{L} at node 214). Without a reflection 208 (e.g., with a reflection 208 having a magnitude of zero), there is no voltage transient at the time 2×T_{P}.

In the example 228, the termination 206 impedance Z_{L} is poorly matched with, and greater than, the line 204 impedance Z₀, which results in a positive reflection 208 back towards the receiver 124 and node 212. When the line 204 settles to an equilibrium value (e.g., after twice the propagation time T_{P}), the superposition value observed at node 212 by the receiver 124 is greater than the transmitted voltage V₀ of the signal (e.g., signal 202) that is initially transmitted (e.g., increased by a reflection voltage V_{R}), but is no more than twice the voltage V₀.

In the example 230, the termination 206 impedance Z_{L} is poorly matched with, and lower than, the line 204 impedance Z₀, which results in a negative reflection 208 back towards the receiver 124 and node 212. When the transmission line 204 settles to an equilibrium value (e.g., after twice the time T_{P}), the superposition value at node 212 is less than the transmitted voltage V₀ (e.g., decreased by a reflection voltage V_{R}).

The receiver 124 enables the computing device 210 to characterize the entire electrical connection 218 (including testing the electrical connection 218 for one or more impedance mismatches) by measuring the voltage at node 212 (e.g., the magnitude of one or more reflections 208 as part of a composite with a step signal 202). In one or more implementations, the computing device 210 is configured to characterize the electrical connection 218 based on a magnitude of the measured reflection 208, e.g., by comparing the magnitude of reflection 208 with the transmitted signal 202 and/or an expected voltage. For example, in at least one implementation, the expected voltage for a perfectly matched transmission line and termination 206 is equal to a magnitude of the signal 202. In at least some other scenarios (e.g., as shown by examples 228, 230), when a load impedance Z_{L} of the termination 206 is greater or lesser than a characteristic impedance Z₀ of the transmission line 204, the reflections 208 are positive or negative, respectively. In at least one such scenario, a reflection 208 with a larger magnitude (e.g., corresponding with a larger deviation from the expected voltage V₀) indicates a larger impedance mismatch.

Opens and shorts are extreme cases of high and low impedances, respectively. If the connection is opened at termination 206, then that defect will drive up the aggregate signal (e.g., a superposition of signal 202 to V₀ and a positive reflection 208 with a reflection voltage V_{R} of the same magnitude), so the line 204 will eventually be observed at twice the voltage V₀ (e.g., after twice the propagation time T_{P}). An open fault such as this would resemble the example 228, except the equilibrium value (V₀+V_{R}) observed by the receiver 124 at node 212 after time 2×T_{P} would be 2×V₀. If the connection at the termination 206 is shorted (e.g., to ground), then that defect will drive down the whole signal (e.g., a superposition of the signal 202 to V₀ and a negative reflection 208 with a reflection voltage V_{R} of the same magnitude), so the line 204 will eventually be observed at ground (e.g., after twice the propagation time T_{P}). A short fault such as this would resemble the example 230, except the equilibrium value (V₀−V_{R}) observed by the receiver 124 at node 212 after time 2×T_{P} would be zero.

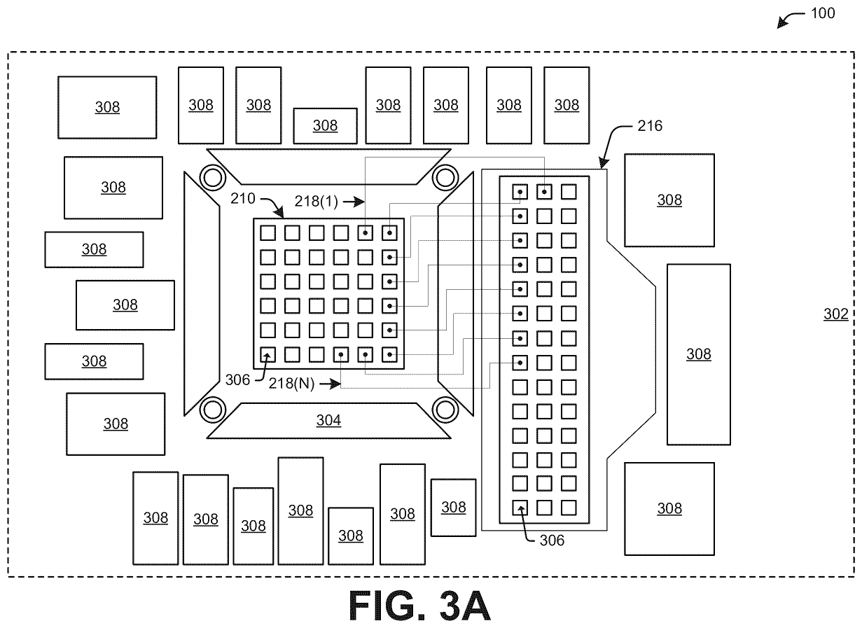

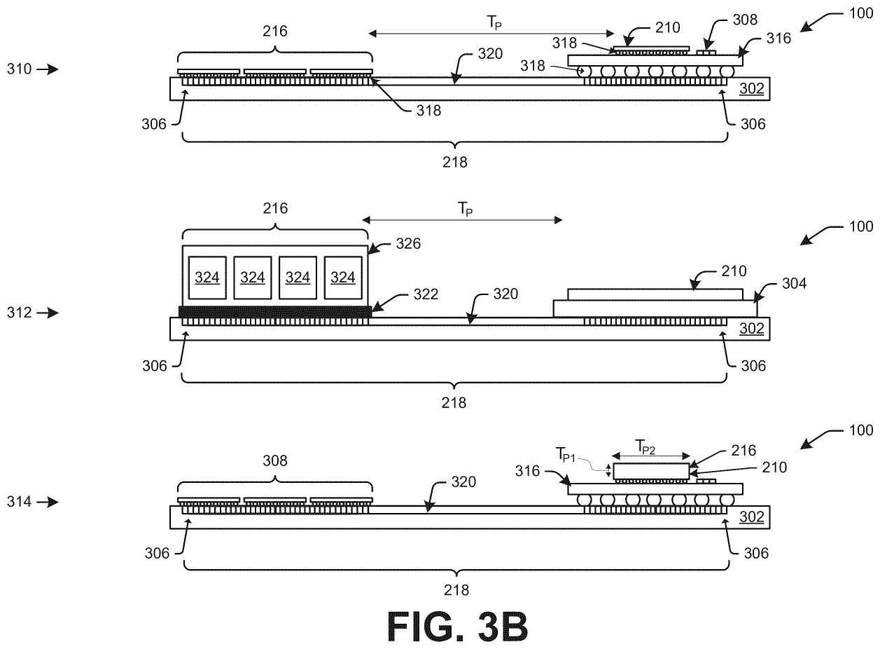

While measurements of extreme voltage values (such as ground or twice the transmitted voltage V₀) indicate edge cases (such as shorts or opens), more refined characterizations are possible, e.g., with measurements having more resolution. By adjusting the reference voltage at node 224 (e.g., for comparison with the sensing location of the receiver 124 at node 212), the system 100 (e.g., and/or the computing device 210) enables the correct verification of whether the electrical connection 218 is opened, shorted, or even marginally faulted. The system 100 (e.g., the device 210) is also configured to adjust the termination values (e.g., of impedance network 222 or of the termination 206 impedance Z_{L}) to confirm or detect a lack of connectivity (e.g., anywhere between devices 210, 216). In an example, the termination values (e.g., of the termination 206 impedance Z_{L}) are adjusted and, by using the one or more (e.g., adjusted) termination value(s), the quality or magnitude of the reflection 208 is varied. The adjustment of the termination 206 impedance Z_{L} is described further at least at FIG. 3A.

The receiver 124, e.g., a differential receiver 124, is configured to detect an incoming signal (such as the combination or superposition of the signal 202 and reflection 208) at different levels, at least in one variation. By adjusting the impedance network 222 (e.g., to different resistor ratios in the voltage divider), the receiver 124 is able to detect whether the behaviors of the incoming signals correspond to a matched-load termination or a mismatched-load termination. In one or more implementations, the transmitter 123 shares the same connections with the termination point (e.g., node 212) as the receiver 124. Furthermore, the response profile of the reflection 208 differs corresponding to not only whether the endpoint is properly terminated or not, but also based on the profile of the signal 202, e.g., whether the signal 202 is a pulse signal, a step signal, etc. Accordingly, based on the different reflection (and superposition or composite response) signatures, the receiver 124 (or, e.g., the device 210) can detect the quality or condition of the electrical connection 218.

Besides measurements of the magnitude of the signal 202 and reflection 208, the system 100 (e.g., the device 210) is also able to characterize the electrical connection 218 using the relative timings of the signal 202 and reflection 208, as is described further at FIG. 2B. In one or more implementations, the computing device 210 is configured to measure a time between the transmission of the signal 202 and the receipt of the reflection 208 of the transmitted signal 202. In at least one implementation, the computing device 210 is configured to calculate a location of a discontinuity of the electrical connection 218 using the measured time.

Fault location information can be used to improve performance and yields. In an implementation configured to calculate the discontinuity location, the location is output and/or saved (e.g., for reporting immediately and/or at a later time). Reporting the discontinuity location (e.g., to a user or to an operating system, such as the operating system 104) enables the troubleshooting and repair of the discontinuity. For example, locating (e.g., isolating) the discontinuity to a particular connection facilitates repair of that connection, such as the tightening of a connector. Repair a faulty connection can include making functional previously non-functional devices 210, improving the performance of marginally performing devices 210, etc. Discontinuity location information can also be used to improve failure analysis, system design, and/or assembly processes.

FIG. 2B depicts examples of transmission lines 204 forming an electrical connection 218 between a computing device 210 and a separate device 216 in the processing system 100. For illustrative purposes, the electrical connection 218 of FIG. 2B includes multiple transmission lines 204 (e.g., any suitable number of lines 204(1), 204(2), etc., to line 204(N)). As in FIG. 2A, although the transmission line 204 is illustrated as between the nodes 212, 214, in at least some cases, the transmission line 204 (e.g., in aggregate, including lines 204(1)-204(N)) is considered to include nodes 212, 214 (e.g., portions of the devices 210, 216) and to extend from (and couple) the device 210 (e.g., the transmitter 123 and/or receiver 124 in the device 210, as shown at FIG. 2A) to the termination 206 in the device 216. In one or more examples, the transmission lines 204 of FIG. 2B represent portions of the transmission line 204 of FIG. 2A, each with corresponding propagation times T_{P} (e.g., times T_{P1}, T_{P2}, T_{PN}) that sum to the total propagation time T_{P} of the transmission line 204 of FIG. 2A. In the event of connectivity faults (such as an open between interconnect interfaces), the awareness of these various propagation times T_{P}, combined with the measurement of a time between the transmission of the signal 202 and the receipt of the reflection 208, enables the computing device 210 to calculate a location of a discontinuity of the electrical connection 218.

In some examples, a first transmission line 204(1) represents at least an interconnect interface on a package of the computing device 210 (e.g., an interconnect interface between the transmitter 123 and receiver 124 in the computing device 210 and a PCB or other substrate having an electrical trace coupling the transmitter 123 and receiver 124 with the separate device 216); a second transmission line 204(2) represents at least the electrical trace in the substrate (e.g., PCB); and a third transmission line 204(N) represents at least an interconnect interface on the separate device 216, between the electrical trace in the substrate and the termination 206 in the device 216. In at least one such example, the computing device 210 is coupled with the PCB or other substrate, and the device 210 is coupled with the separate device 216 by the PCB or other substrate.

The computing device 210 and/or the separate device 216 are, in some variations, coupled with the PCB or other substrate by a socket or other connector. In such an example, the first transmission line 204(1) represents a first interconnect interface of the package of the device 210 and a socket coupling the first interconnect interface with a second interconnect interface on the PCB. In the same or another example, the second transmission line 204(2) represents the second interconnect interface on the PCB, a third interconnect interface on the PCB (e.g., to couple with a fourth interconnect interface of the separate device 216), and multiple vias and electrical traces in the PCB electrically coupling the second and third interconnect interfaces (and so coupling the transmitter 123 and receiver 124 with the separate device 216). In these or other examples, the third transmission line 204(N) represents the fourth interconnect interface of the separate device 216 and a socket or other connector (such as a compression connector, e.g., a bed-of-nails connector) between (and coupling) the termination 206 in the device 216 and the PCB.

The electrical connection 218 includes the electrical trace(s) in the substrate (e.g., PCB) and the first, second, third, and fourth interconnect interfaces, as well as any connectors (such as sockets) or solder coupling the interconnect interfaces. In one or more variations, the first, second, third, and fourth interconnect interfaces on the substrate and devices 210, 216 are conductive pads, such as bond or land pads.

The structures and techniques described (e.g., at FIG. 2A and here at FIG. 2B) are deployed by a system on a chip (SoC) device 210, in one or more implementations, with the computing device 210 including an SoC in a package of the device 210 and configured to test a continuity of the electrical connection 218 using the measured reflection 208. In one such example, an IC package includes the computing device 210 on a single semiconductor die, e.g., with the transmitter 123 and receiver 124 on the die as at least part of an I/O interface of the SoC device 210 to external components, such as a separate DRAM or other memory device 216. The computing device 210 (e.g., the transmitter 123 in the device 210) is configured to communicate the signal 202 (e.g., and other signals, such as data) to the separate device 216 via the transmission line(s) 204 between the devices 210, 216. The receiver 124 is configured to receive the reflection 208 of the transmitted signal 202 (as well as other signals, such as data) communicated by the transmission line(s) 204 between the computing and separate devices 210, 216. In at least one implementation, the techniques (e.g., locating a discontinuity in the electrical connection 218) are employed by the SoC device 210 (e.g., a controller of the SoC, such as the CPU 102), for example, with the SoC device 210 as a portion of the processing system 100 that includes the CPU 102.

Examples 232, 234, 236 show voltages on the transmission line 204 (e.g., at node 212) for different discontinuities in the electrical connection 218, e.g., at different locations along the electrical connection 218. In examples 232, 234, 236 of FIG. 2B (as in the examples 226, 228, 230 at FIG. 2A), a step signal 202 of voltage V₀ is transmitted from the computing device 210 (e.g., by a transmitter 123) down the (aggregated) transmission line 204 towards the second device 216. In one or more implementations, the computing device 210 is configured to measure a time between the transmission of the signal 202 and the receipt of the reflection 208 of the transmitted signal 202. In at least one implementation, the computing device 210 is configured to calculate a location of a discontinuity of the electrical connection 218. In one such implementation, the computing device 210 is configured to calculate the location of the discontinuity of the electrical connection 218 using the time measured between the transmission and receipt of the signal 202 and reflection 208, respectively. The measurement by the computing device 210 of the time between the transmission of the signal 202 and the receipt of the reflection 208, as well as comparison by the computing device 210 of the measured time with various propagation times T_{P} (e.g., times T_{P1}, T_{P2}, T_{PN}), enables the computing device 210 to calculate a location of a discontinuity in the electrical connection 218.

In the example 232, a discontinuity (e.g., an open fault) in the electrical connection 218 is between transmission lines 204(1), 204(2)). In at least one scenario, the computing device 210 identifies (e.g., calculates) the location of the discontinuity in the electrical connection 218 (e.g., at an end of the line 204(1) opposite the device 210) by measuring twice a propagation time T_{P1} between the transmission and receipt of the signal 202 and reflection 208, respectively. In one such scenario, for example, an SoC device 210 is in a package coupled with a socket on a PCB (e.g., with the socket as at least part of the transmission line 204(1)), and the device 210 identifies an open between the socket and the PCB. In another scenario, the device 210 is coupled with a socket on a PCB, and the device 210 identifies an open between the device 210 and the socket, e.g., due to measuring a time less than twice a propagation time T_{P1} (such as no time or nearly no time) between the transmission and receipt of the signal 202 and reflection 208, respectively.

In the example 234, a discontinuity (e.g., an open fault) in the electrical connection 218 is between transmission lines 204(2), 204(N)). In at least one scenario, the computing device 210 identifies the location of the discontinuity in the electrical connection 218 (e.g., at an end of the line 204(2) opposite the device 210) by measuring twice a sum of the propagation times T_{P1}, T_{P2} between the transmission and receipt of the signal 202 and reflection 208, respectively. In one such scenario, the separate device 216 is in a socket on a PCB (e.g., with the PCB as at least part of the transmission line 204(2)), and the device 210 identifies an open between the PCB and the remote socket (e.g., with the socket at least part of the line 204(N)).

In the example 236, a discontinuity (e.g., an open fault) in the electrical connection 218 is at node 214. In at least one scenario, the computing device 210 identifies the location of the discontinuity in the electrical connection 218 (e.g., at an end of the line 204(N) opposite the device 210) by measuring twice a sum of the propagation times T_{P1}, T_{P2}, T_{PN} between the transmission and receipt of the signal 202 and reflection 208, respectively. In one such scenario, the separate device 216 is in a socket on a PCB, and the device 210 identifies an open between the device 216 and the socket, e.g., with the socket at least part of the line 204(N).

When the electrical connection 218 is continuous between devices 210, 216 and includes multiple transmission lines 204 (e.g., lines 204(1), 204(2), 204(N), etc.) and multiple imperfectly matched transitions between lines 204, the computing device 210 (e.g., the receiver 124) can receive and measure multiple reflections 208 and characterize the entirety of the electrical connection 218 (e.g., each and every transition) using the multiple reflections 208. In at least one variation, the computing device 210 is configured to characterize the electrical connection 218 based on one or more magnitudes of one or more measured reflections 208. In a variation, the computing device 210 is configured to characterize the electrical connection 218 based on multiple times measured between the transmission of the signal 202 and the receipt of multiple reflections 208. Smaller measured times (e.g., twice a propagation time T_{P1} or less) between the transmission and receipt of the signal 202 and reflection 208, respectively (or between the receipt of multiple reflections 208) indicate faults nearer to the device 210 (or each other). Larger measured times indicate faults further from the device 210 (or between sequential faults).

FIGS. 3A and 3B are block diagrams of a computing device having multiple transmitters and receivers and multiple electrical connections to at least one separate device.

FIG. 3A depicts the processing system 100, including the computing device 210 and the separate device 216, on (and coupled through) a PCB 302. The device 210 is coupled to the PCB 302 by a socket 304. The device 216 is also on the PCB 302, and devices 210, 216 are coupled by the PCB 302. Devices 210, 216 are coupled (e.g., electrically coupled) by multiple electrical connections 218 (e.g., connection 218(1) through connection 218(N)). The connections 218 illustrated in FIG. 3A represent which of the multiple interconnect interfaces 306 shown on the device 210 are coupled to other interconnect interfaces 306 on the device 216, but these connections 218 do not necessarily show routing paths between the interfaces 306. In at least one implementation, the multiple electrical connections 218(1)-218(N) include electrical connections 218 not shown in FIG. 3A, e.g., for illustrative purposes. In one example, the multiple electrical connections 218(1)-218(N) include connections 218 to a vast majority (e.g., nearly every) of interconnect interfaces 306 on the separate device 216.

The computing device 210 includes multiple transmitters 123 and receivers 124, in one or more implementations, e.g., with at least some of the interconnect interfaces 306 on the device 210 each coupled with one of the multiple transmitters 123 and one of the multiple receivers 124, as described at least at FIG. 2A. In one or more variations, the processing system 100 includes multiple electrical connections 218 between the computing device 210 and the separate device 210, and the computing device 210 is configured to characterize at least some of these electrical connections 218, as described at least at FIGS. 2A and 2B. In one such example, the computing device 210 is an SoC device 210 (e.g., an SoC having multiple transmitters 123 and receivers 124 on a single chip in a package), the separate device 216 is a memory device 216 (e.g., an LPCAMM2 device 216), and the SoC device 210 is configured to test a continuity of the multiple electrical connections 218 between devices 210, 216 using multiple measured reflections 208. For example, each of the multiple electrical connections 218 between devices 210, 216 is tested as described at least at FIGS. 2A and 2B, e.g., with a corresponding transmitter 123 and receiver 124.

The PCB 302 is a substrate (such as a motherboard or other board) on which components (such as devices 210, 216) can be mounted and electrically coupled, e.g., into one or more electrical circuits. In variations, the PCB 302 includes alternating conductive and insulating layers, e.g., with electrical traces running in the conductive layers and vias extending through the insulating layers and coupling between traces in separate conductive layers. The PCB 302 includes multiple interconnect interfaces 306 configured to couple with interfaces 306 on devices 210, 216, e.g., parallel with and directly under interfaces 306 on devices 210, 216.

The computing device 210 (e.g., an IC package of the device 210) is coupled with the PCB 302 by multiple interconnect interfaces 306, which are much as described at least at FIG. 2A (e.g., land pads). The second device 216 is similarly coupled with the PCB 302 by multiple interconnect interfaces 306 (much as described at FIG. 2A), and devices 210, 216 are coupled by the PCB 302.

In the example of FIG. 3A, a first interconnect interface 306 (e.g., a conductive pad) on the package of the device 210 and a second interconnect interface 306 (e.g., another conductive pad) on the PCB 302 are coupled by the socket 304, and a third interconnect interface 306 (e.g., a third conductive pad) on the PCB 302 and a fourth interconnect interface 306 (e.g., a fourth conductive pad) on an LPCAMM2 device 216 are coupled by an LPCAMM2 connector (not shown, e.g., a compression connector between the PCB 302 and the LPCAMM2 device 216). The PCB 302 includes at least one electrical trace, and the second and third interconnect interfaces 306 on the PCB 302 are coupled by the electrical trace. In this example, the corresponding electrical connection 218 between the devices 210, 216 includes the electrical trace and the first, second, third, and fourth interfaces 306. The electrical connection 218 (e.g., including the electrical trace) couples a transmitter 123 and receiver 124 in the computing device 210 (e.g., as described at FIG. 2A) with the memory device 216.

The socket 304 includes any suitable structure(s) for coupling the interconnect interfaces 306 of the device 210 and PCB 302, such as socket pins or other conductive structures providing spring force to make and maintain contact with interfaces 306 of the device 210 and the PCB 302. In other examples (e.g., as described at least at FIG. 3B), interconnect interfaces 306 are coupled by other structures, such as solder, etc. Although FIG. 3A depicts devices 210, 216 as having pad interfaces 306, another example of processing system 100 uses other suitable interconnect interfaces 306, such as pin interfaces 306 on a PGA package.

In at least one implementation, one or both of devices 210, 216 include interconnect interfaces 306 not shown in FIG. 3A, e.g., for illustrative purposes. The device 210 (e.g., the package and interconnect interfaces 306 of the device 210) is configured to couple with one or more other devices 308 through the PCB 302, e.g., by suitable interconnect interfaces 306. In the example of FIG. 3A, the computing device 210 is coupled with multiple devices 308 on the PCB 302 by electrical connections 218 (not shown) through the PCB 302, e.g., by interfaces 306 both shown and not shown in FIG. 3A. In one or more cases, the computing device 210 is configured to characterize (e.g., test a continuity of) one or more of the electrical connections 218 (not shown) between the computing device 210 and the one or more other devices 308, e.g., as described at FIGS. 2A and 2B, using a transmitter 123 and receiver 124 in the device 210.

The multitude of electrical connections 218 between devices 210, 216 enables additional communications between devices 210, 216 and control of the device 216 by the device 210, e.g., through the use of sideband signals. For example, in one or more variations, the computing device 210 is configured to set a termination impedance (e.g., a load impedance Z_{L} of a termination 206, as described at FIGS. 2A and 2B) of a first electrical connection 218 (e.g., through a first pair of interconnect interfaces 306 on devices 210, 216) to the separate device 216 by transmitting a control signal to the separate device 216 by a second electrical connection 218 to the separate device 216 (e.g., through a second pair of interconnect interfaces 306 on devices 210, 216).

By adjusting the impedance of the termination 206 through a second (e.g., sideband or control) connection 218, the computing device 210 can confirm a detected connectivity (or detected lack of connectivity) of the first electrical connection 218. In a scenario with a continuous first electrical connection 218, an observed voltage at the computing device 210 end of the first electrical connection 218 varies in an expected manner corresponding with a varying of the impedance of the termination 206 at the separate device 216 end of the first electrical connection 218. In a scenario with a disconnected first electrical connection 218, an observed voltage at the computing device 210 end of the first electrical connection 218 will not vary as expected when the impedance of the termination 206 at the separate device 216 end of the first electrical connection 218 is varied.

FIG. 3B depicts examples 310, 312, 314 of processing systems 100 having multiple electrical connections 218 coupling a computing device 210 and a separate device 216.

In the example 310, the processing system 100 includes the computing device 210 coupled with the PCB 302 (e.g., a package of the device 210 coupled by a substrate 316), which is coupled by solder 318 to the device 210 above and to the PCB 302 below. The separate device 216 is coupled with the PCB 302 by solder 318, and devices 210, 216 are coupled by the PCB 302. Groups of first interconnect interfaces 306 on the device 210 and groups of second interfaces 306 on the PCB 302 are coupled by the substrate 316 and by solder 318, and groups of third interfaces 306 on the PCB 302 and groups of fourth interfaces 306 on the separate device 216 are coupled by solder 318. The PCB 302 includes multiple electrical traces 320, and the groups of second and third interfaces 306 on the PCB 302 are coupled by the multiple traces 320. In this example, the electrical connections 218 corresponding to and between pairs of coupled first and second interconnect interfaces 306 on devices 210, 216 include the corresponding electrical traces 320 and corresponding first, second, third, and fourth interfaces 306 (as well as solder 318 and substrate 316 of the device 210).

One or more electrical connections 218 couple one or more corresponding transmitter 123 and receiver 124 pairs in the computing device 210 (e.g., as described at FIG. 2A) with the separate device 216. The computing device 210 is configured to characterize one or more (e.g., all) of the one or more electrical connections 218. As depicted in the example 310, a propagation time T_{P} (e.g., elapsed during a traversal by signals or reflections between devices 210, 216) spans much of the PCB 302, e.g., including individual propagation times T_{P} for each of the portions of electrical connections 218, such as traces 320, etc. By measuring times reflections are received, the computing device 210 can locate discontinuities of electrical connections 218, e.g., between interconnect interfaces 306 and as described at FIGS. 2A and 2B.

The package of the computing device 210 is also coupled to one or more other devices 308 through substrate 316 (e.g., and traces included in substrate 316) and solder 318. Substrate 316 is a PCB (e.g., similar to the PCB 302) with one or more conductive layers between insulating layers, with electrical traces running in the conductive layer(s), and with interconnect interfaces 306 configured to couple with other interfaces 306 (e.g., on devices 210, 308 and the PCB 302). In one or more variations, the computing device 210 is configured to characterize one or more electrical connections between the device 210 and other devices 308, e.g., as described at FIGS. 2A and 2B.

In the example 312, a package of the computing device 210 is coupled with the PCB 302 by socket 304. The separate device 216 is coupled with the PCB 302 by a socket or connector 322, and devices 210, 216 are coupled by the PCB 302. The electrical connections 218 of the example 312 are similar to those of the example 310, but the groups of first interconnect interfaces 306 on the device 210 and the groups of fourth interfaces 306 on the separate device 216 are coupled with the groups of second and third interfaces 306 on the PCB 302, respectively, by the socket 304 and the connector 322.

The separate device 216 includes multiple chips or packages 324 on a substrate 326 (e.g., a PCB). The substrate 326 of the separate device 216 is coupled with the PCB 302 by a slot connector 322. In one variation, the separate device 216 is a memory device 216, such as a double data rate (DDR) or other DRAM module. In another variation, the separate device 216 is a CAMM device 216 (e.g., with a substrate 326 parallel with the PCB 302) coupled with the PCB 302 by a compression connector 322.

In the example 314, the computing device 210 and the separate device 216 are separate dies (or groups of dies) in a same package, and devices 210, 216 are coupled by multiple electrical connections internal to the shared package, e.g., with quick propagation times T_{P1} or T_{P2} for short transmission lines entirely within the package. In one implementation, the separate device 216 is an HBM device 216, e.g., a stack of memory dies over or alongside the computing device 210 in the package. In one or more variations, the computing device 210 is configured to characterize one or more electrical connections between devices 210, 216. In one such variation, the computing device 210 characterizes one or more electrical connections between devices 210, 216 during assembly, e.g., to verify connectivity between bonded dies before packaging. Such a connectivity verification can be employed in situations where previously used techniques (such as conventional PCB X-ray) are no longer feasible.

The package containing both of devices 210, 216 is coupled to one or more other devices 308 through multiple electrical connections 218, e.g., electrical traces 320 in the PCB 302. In one or more variations, the computing device 210 is configured to characterize one or more electrical connections 218 between the device 210 and other devices 308.

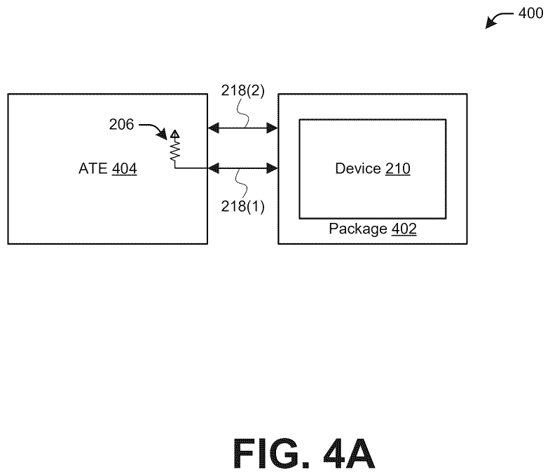

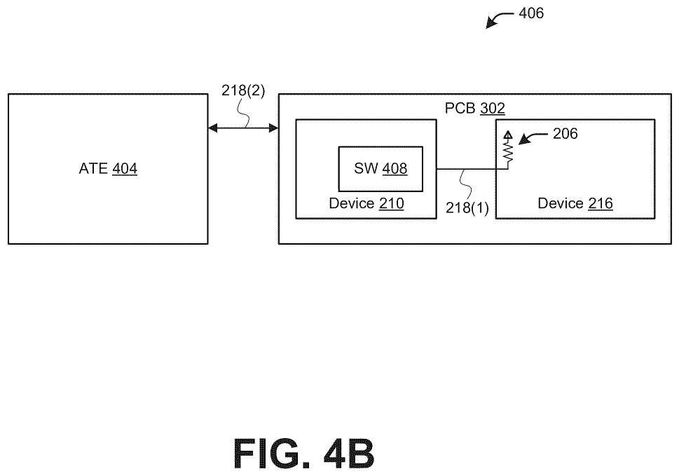

FIGS. 4A and 4B are block diagrams of the computing device in automated test arrangements, for example, coupled with a controller or testing device.

FIG. 4A depicts an example 400 of automated testing the computing device 210 (e.g., an SoC device 210) in a package 402 not coupled with a separate device 216 (e.g., a DRAM device 216). With no separate device 216 coupled with the device 210, one or more interconnect interfaces of the device 210 are available for coupling with an automated test equipment (ATE) 404. In some scenarios, the ATE 404 couples with the device 210, e.g., forming one or more electrical connections 218 (e.g., connections 218(1)) between the device 210 and one or more terminations 206 provided by the ATE 404. In at least one scenario, the ATE 404 couples with the device 210 at interfaces (e.g., data or DQ pins or pads) configured to couple with a DRAM device 216 (e.g., to form one or more electrical connections 218(1)).

In addition to providing one or more terminations 206 for verifying the capability of the computing device 210 to form one or more electrical connections 218(1), the ATE 404 can also provide control or other functionality through one or more electrical connections 218(2), e.g., sideband connections 218(2). In one case, the ATE 404 controls the computing device 210 through a connection 218(2) during automated testing of the device 210, e.g., using a JTAG (Joint Test Action Group) interface. In another case, the ATE 404 and the computing device 210 communicate (e.g., test commands and test results) via or through a JTAG (or other) connection 218(2). In either case, the connections 218(2) enable the adjusting of a load impedance of termination 206, e.g., to verify a continuity of an electrical connection 218(1). In some scenarios, test instructions are received by the computing device 210 from the ATE 404, which is configured to act as a controller or test device (e.g., by providing test instructions), and test results are transmitted by the computing device 210 to the ATE 404.

The employment of the ATE 404 enables the verification of interface functionality of the computing device 210, even without a coupled separate device 216, e.g., at various states of assembly and/or of various levels of complexity.

FIG. 4B depicts an example 406 of automated testing of the computing device 210 coupled with a separate device 216 (e.g., a DRAM device 216). Devices 210, 216 are coupled on and by a PCB 302. In at least one implementation, the PCB 302 is a package substrate, and devices 210, 216 are co-packaged, e.g., with the computing device 210 on a first IC die (or first group of dies) in a package and the separate device 216 on a second, separate IC die (or separate group of dies) in the package. With the separate device 216 coupled with the computing device 210, in some scenarios, one or more interconnect interfaces of the device 210 are not available for coupling with the ATE 404, e.g., into one or more electrical connections 218(1). In at least one such scenario, however, one or more terminations 206 are provided by the separate device 216, and one or more electrical connections 218(1) are formed between the computing device 210 and the one or more terminations 206 of the separate device 216.

Even without electrical connections 218(1), the ATE 404 can provide control or other functionality through one or more (e.g., sideband and/or JTAG) connections 218(2), as described at FIG. 4A. In at least one case, the computing device 210 receives software 408, such as firmware, from the ATE 404 by the one or more connections 218(2). In one such case, the software 408 enables control by the computing device 210 of the one or more terminations 206 of the separate device 216, e.g., by the one or more connections 218(1) between devices 210, 216. In some scenarios, test instructions are received by the computing device 210 from the ATE 404, and test results are transmitted by the computing device 210 to the ATE 404.

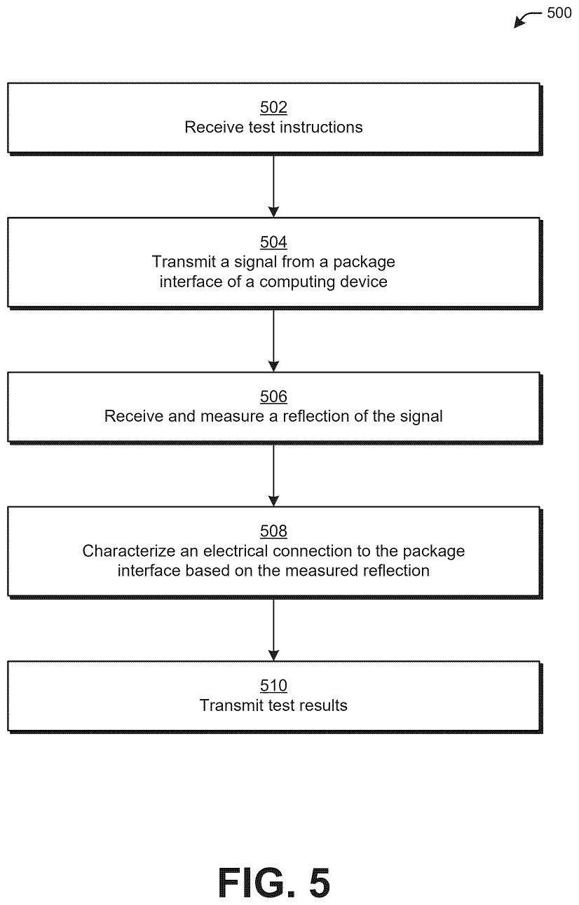

FIG. 5 depicts a procedure in an example 500 implementation of characterizing an electrical connection. The procedure is implemented by, for example, the computing system 100.

In some scenarios, test instructions are optionally received by a computing device (such as the device 210) from another device (block 502), such as a controller or test device, e.g., the ATE 404, as described at least at FIGS. 4A and 4B.

A signal is transmitted out from a computing device (block 504). For example (as described at least at FIG. 2A), the transmitter 123 transmits the signal 202 out from and through an interconnect interface (represented by the node 212) of a package of the computing device 210.

A reflection of the signal is received and measured (block 506). In at least one case (as described at least at FIG. 2A), the receiver 124 (e.g., of the computing device 210) receives and measures the reflection 208 at the interconnect interface of the package of the computing device 210.

An electrical connection to the computing device is characterized based on the measured reflection (block 508). In one example (as described at least at FIG. 2A), the electrical connection 218 is to the package interface (represented by node 212) and is characterized based on a magnitude of the measured reflection 208. The electrical connection 218 at the package interface is to the computing device 210, and the electrical connection 218 is between a separate device 216 and the computing device 210 such that the separate device 216 is coupled to the computing device 210 at the package interface and through the electrical connection 218. In one or more implementations, the characterization of the electrical connection 218 includes testing a continuity of the electrical connection 218 between the computing and separate devices 210, 216.

In some instances (as described at least at FIG. 2B), the characterization of the electrical connection 218 includes measuring a time between the transmission of the signal 202 and the receipt of the reflection 208. In some such instances, the characterization of the electrical connection 218 includes calculating a location of a discontinuity in the electrical connection 218 using the time measurement.

In some scenarios, test results are optionally transmitted by the computing device to another device (block 510), such as a controller or test device that provided test instructions, e.g., as described at least at FIGS. 4A and 4B.

A number of implementations have been described. Nevertheless, it will be understood that various modifications may be made without departing from the spirit and scope of the disclosure. Accordingly, other implementations are within the scope of the following claims.

What is claimed is:

1. A computing device, comprising:
a transmitter in a package, the transmitter coupled to an interface of the package and configured to transmit a signal to a separate device via the interface; and
a receiver in the package, the receiver coupled to the interface and configured to receive and measure a reflection of the transmitted signal, the measured reflection used to characterize an electrical connection between the computing device and the separate device.

2. The computing device of claim 1, wherein the computing device is configured to characterize the electrical connection based on a comparison between a first magnitude of the transmitted signal and a second magnitude of the measured reflection.

3. The computing device of claim 1, wherein the measured reflection is used to detect a discontinuity in the electrical connection.

4. The computing device of claim 1, wherein:
the computing device comprises a system on a chip in the package;
the system on the chip comprises the transmitter and the receiver;
the separate device is a memory device;
the interface of the package is a first conductive pad on the package; and
the interface of the package is coupled with an interface on the memory device, the interface on the memory device a second conductive pad on the memory device.

5. The computing device of claim 1, wherein:
the transmitter is configured to communicate the signal to the separate device via a transmission line between the computing device and the separate device; and
the receiver is configured to receive the reflection of the transmitted signal communicated via the transmission line between the computing device and the separate device.

6. The computing device of claim 1, wherein:
the package is coupled with a substrate, the substrate comprising a first interface of the substrate coupled with the interface of the package;
the separate device is coupled with the substrate, the substrate comprising a second interface of the substrate and an electrical trace, the electrical trace coupling the first interface of the substrate and the second interface of the substrate, the second interface of the substrate coupled with an interface of the separate device; and
the electrical connection comprises the electrical trace and the interface of the package, the first interface of the substrate and the second interface of the substrate, and the interface of the separate device.

7. The computing device of claim 6, wherein the package is coupled with the substrate by a socket, the socket coupling the interface of the package and the first interface of the substrate.

8. The computing device of claim 1, further comprising:
a plurality of transmitters, comprising the transmitter;
a plurality of receivers, comprising the receiver; and
a plurality of interfaces, comprising the interface of the package, wherein:
the computing device is coupled with a substrate by the plurality of interfaces and with the separate device by the substrate;
a plurality of electrical connections is between the computing device and the separate device, the plurality of electrical connections comprising the electrical connection; and
the computing device is configured to characterize the plurality of electrical connections.

9. The computing device of claim 1, wherein the measured reflection of the transmitted signal is compared to a reference voltage, and the receiver is configured to adjust the reference voltage.

10. The computing device of claim 1, wherein the receiver is configured to adjust a load impedance of the receiver.

11. The computing device of claim 1, wherein the computing device is configured to measure a time between transmission of the signal and receipt of the reflection of the transmitted signal, the time used to calculate a location of a discontinuity.

12. The computing device of claim 1, wherein:
the computing device is coupled with a substrate and with the separate device by the substrate, the electrical connection between the computing device and a first interface of the separate device;
the computing device and the separate device are coupled through the substrate by a second interface of the separate device; and
the computing device is configured to set a termination impedance of the electrical connection at the first interface of the separate device by transmitting a control signal to the separate device via the second interface of the separate device.

13. A computer-implemented method, comprising:
transmitting a signal out from a package interface of a computing device;
receiving and measuring a reflection of the signal at the package interface; and
characterizing an electrical connection to the package interface based on the measured reflection.

14. The computer-implemented method of claim 13, wherein:
a separate device is coupled to the computing device at the package interface and through the electrical connection;
the characterizing the electrical connection to the package interface is based on a magnitude of the measured reflection; and
the characterizing the electrical connection comprises testing a continuity of the electrical connection between the computing device and the separate device.

15. The computer-implemented method of claim 13, wherein the characterizing the electrical connection to the package interface comprises:
measuring a time between transmission of the signal and receipt of the reflection; and
calculating a location of a discontinuity in the electrical connection using the time.

16. The computer-implemented method of claim 13, further comprising:
receiving test instructions from a second device; and
transmitting test results to the second device.

17. A computing system, comprising:
a package on a substrate, a first interconnect interface of the package coupled with a second interconnect interface of the substrate, the package configured to couple with one or more devices through the substrate;
a transmitter in the package, the transmitter coupled to the first interconnect interface and configured to transmit a signal from the package to at least one device of the one or more devices via the second interconnect interface; and
a receiver in the package, the receiver coupled to the first interconnect interface and configured to measure a reflection of the transmitted signal, the measured reflection used to characterize an electrical connection between the package and the at least one device.

18. The computing system of claim 17, wherein:
the substrate comprises an electrical trace, the electrical trace coupling the transmitter and the receiver with the at least one device, the electrical connection comprising the electrical trace and the first interconnect interface and the second interconnect interface; and
a system on a chip in the package comprises the transmitter and the receiver, the system on the chip configured to test a continuity of the electrical connection using the measured reflection.

19. The computing system of claim 17, wherein the computing system is configured to:
measure a time between transmission of the signal and receipt of the reflection of the transmitted signal;
characterize the electrical connection based on a magnitude of the measured reflection; and
calculate a location of a discontinuity of the electrical connection using the time.

20. The computing system of claim 17, further comprising the at least one device, wherein:
the first interconnect interface is one of a plurality of third interconnect interfaces, the package comprising the third interconnect interfaces coupled with a plurality of transmitters and a plurality of receivers in the package;
the second interconnect interface is one of a plurality of fourth interconnect interfaces, the substrate comprising the fourth interconnect interfaces;
the package is coupled with the substrate by the third interconnect interfaces and the fourth interconnect interfaces;
the at least one device comprises a plurality of fifth interconnect interfaces;
the substrate comprises a plurality of sixth interconnect interfaces;
the at least one device is coupled with the substrate by the fifth interconnect interfaces and the sixth interconnect interfaces; and
the package is coupled with the at least one device by the third interconnect interfaces, the fourth interconnect interfaces, the fifth interconnect interfaces, and the sixth interconnect interfaces.
